(19) United States
(12) Patent Application Publication
(10) Pub. No.: US 2005/0196925 A1
(43) Pub. Date: Sep. 8, 2005

(54) Method of forming stress-relaxed SiGe buffer layer

(76) Inventors: Sang Hoon Kim, Daejeon -shi (KR); Kyu Hwan Shim, Daejeon-shi (KR); Jin Yeong Kang, Daejeon-shi (KR)

Correspondence Address: MAYER, BROWN, ROWE & MAW LLP, 1909 K STREET, N.W., WASHINGTON, DC, 20006, US

(21) Appl. No.: 11/018,647

(22) Filed: Dec. 22, 2004

(30) Foreign Application Priority Data
Dec. 22, 2003 (KR) 2003-95046
Mar. 11, 2004 (KR) 2004-16498

(51) Int. Cl. H01L 29/739

(52) U.S. Cl. 438/285

(57) ABSTRACT

Provided is a method of forming a stress-relaxed SiGe buffer layer on a silicon substrate using a reduced pressure chemical vapor deposition (RPCVD) technique. The method includes: forming a graded composition layer having a predetermined germanium composition gradient on a silicon substrate; forming and thermally annealing a first constant composition layer having a predetermined germanium composition on the graded composition layer; removing the first constant composition layer by a predetermined thickness to planarize a surface; and forming a second constant composition layer on the first constant composition layer to form a SiGe buffer layer having the graded composition layer and the constant composition layer. A strained silicon or SiGe channel can be formed in a silicon-based MOSFET device or a MODFET device by forming the stress-relaxed SiGe buffer layer that has a relatively thin thickness, a low surface dislocation density, and a surface roughness similar to bulk silicon, and thus a device having excellent channel conductivity and high frequency characteristics can be manufactured.

### CROSS-REFERENCE TO RELATED APPLICATION

This application claims priorities to and the benefit of Korean Patent Application Nos. 2003-98046 and 2004-16498, filed Dec. 22, 2003 and Mar. 11, 2004, the disclosure of which are incorporated herein by reference in its entirety.

### BACKGROUND

1. Field of the Invention

The present invention relates to a method of forming a silicon-germanium (SiGe) buffer layer and, more particularly, to a method of forming a stress-relaxed SiGe buffer layer which can be applied to the manufacture of a modulation doped field effect transistor (MODFET) or a metal oxide semiconductor field effect transistor (MOSFET) which uses a Si/SiGe heterojunction.

2. Discussion of Related Art

Researches on a device having a Si/SiGe heterojunction structure have been performed for the past several decades. According to research results, it is known that electron mobility in a tensily strained Si channel formed on a SiGe single crystal is higher than that in a bulk silicon layer, and hole mobility in a compressively strained SiGe layer having a high content of germanium is 5 times faster than that in the silicon layer. Therefore, when these are applied to a silicon-based device, it is expected that a device of high mobility and high speed can be achieved.

A lattice strain “f” which is a major parameter in a Si/SiGe heterojunction structure using a SiGe quantum well structure can be defined by Equation 1:
f=(a_{layer}−a_{sub})/a_{sub} Equation 1

where a_{sub} denotes a lattice constant of a substrate, and a_{layer} denote a lattice constant of a deposited layer.

A lattice strain f on silicon and germanium is 4.2%, and different equilibrium critical thicknesses t_{c} are given according to a concentration of the germanium. As the concentration of the germanium is increased, the t_{c} value is decreased. In case of a thickness less than t_{c}, a lattice structure exists as a stable state by elastic deformation to a square, whereas in case of a thickness more than t_{c}, energy required to produce misfit dislocation becomes smaller than elastic deformation energy of a deposited SiGe, so that a stress relaxation phenomenon occurs due to the misfit dislocation. The t_{c} value depends on a nucleus production position or a propagation mechanism of the dislocation as well as a deposition temperature.

Since a silicon or SiGe epitaxial layer and an active device are grown on a stress-relaxed SiGe buffer layer, the SiGe buffer layer has to satisfy the following requirements.

First, a stress resulting from the misfit dislocation should be sufficiently relaxed.

Second, a surface of the buffer layer should be smooth. A rough surface with a damascene pattern reduces conductivity due to dispersion of carriers.

Third, the misfit dislocation which may occur while the stress is relaxed should not be propagated to a surface of the buffer layer. Dislocation which is propagated to the surface of the buffer layer may serve as a defect in an active device formed thereon to thereby degrade device characteristics or generate a leakage current.

Finally, for the sake of commercialization, the buffer layer should be formed in a relatively small thickness to increase the manufacturing yield.

Many researches on the SiGe buffer layer have been reported so far, but since it is difficult to form a SiGe buffer layer which satisfies the above requirements, reports on a device which employs the SiGe buffer layer are not so much. A research on growth of the SiGe buffer layer reported that a growth method based on composition variation of germanium has shown the most excellent characteristics. The composition variation growth method includes increasing a composition gradient of the germanium constantly or stepwisely (5˜20% Ge/μm) until desired germanium composition is obtained, and depositing the SiGe buffer layer to several micrometers of thickness while constantly maintaining the desired germanium composition.

The misfit dislocation exists overall in a graded layer of germanium composition, i.e., a graded Si_{1-X}Ge_{X} layer as well as at an interface between a silicon substrate and a SiGe layer. Therefore, it is required that stress relaxation is significantly achieved and a branch is formed due to an interaction between dislocations to thereby prevent the dislocation from being propagated to a part of a constant composition layer, i.e., a constant Si_{1-Y}Ge_{Y} layer. However, the composition variation growth method has disadvantages in that a deposition process time is lengthened, which leads to the low manufacturing yield and surface roughness is tens of nano meters which is too rough to be practically applied to a device since a thickness more than several micrometers is required.

In order to solve these problems, several methods which can grow the SiGe buffer layer to a small thickness have been suggested. Most of cases form defects at an interface and use the defects as a source of forming the misfit dislocation. As representative examples, there are a method of forming a low temperature silicon epitaxial layer, an ion implantation method, and a method of adding an additive such as Sb.

In case of growing a silicon or SiGe single crystal layer at a temperature of about 400° C. using a molecular beam epitaxy (“MBE”) method, the low temperature epitaxial growth method grows it to an amorphous one in case more than a critical thickness and causes defects due to a void even in case less than the critical thickness. The created defect serves as a source of the misfit dislocation to perform the stress relaxation. As a result, the buffer layer can be grown to a small thickness. However, this method is also difficult to be practically applied to a device because a low temperature silicon layer should be grown by the MBE method.

An ion implantation method is such that hydrogen or germanium ions are implanted before or after the growth of the SiGe buffer layer and then a thermal annealing process is performed. This method generates voluntarily point defects on a silicon substrate and uses the point defects as a source of the misfit dislocation production, so that the dislocation is propagated to the silicon substrate in which the stress is relaxed and the defects are formed to reduce a thickness of the buffer layer. However, this method cannot also obtain a satisfactory result.

Besides the above-described methods, a research for forming a SiGe layer on a silicon-on-insulator (“SOI”) substrate is actively being performed.

### SUMMARY OF THE INVENTION

The present invention is directed to a method of forming a stress-relaxed SiGe buffer layer which satisfies applicable requirements to a device.

The present invention is also directed to a method of forming a stress-relaxed SiGe buffer layer which has a relatively small thickness, a reduced surface dislocation density, and a surface roughness similar to bulk silicon.

One aspect of the present invention is to provide a method of forming a stress-relaxed SiGe buffer layer, comprising: forming a graded composition layer having a predetermined germanium composition gradient on a silicon substrate; forming and thermally annealing a first constant composition layer having a predetermined germanium composition on the graded composition layer; removing the first constant composition layer by a predetermined thickness to planarize a surface; and forming a second constant composition layer on the first constant composition layer to form a SiGe buffer layer having the graded composition layer and the constant composition layer.

The graded composition layer is formed by a SiGe deposition process and a thermal annealing process for increasing misfit dislocation, and the deposition process and the thermal annealing process are repeatedly performed by a predetermined number of times.

The thermal annealing process is performed at a temperature of 900 to 1000° C. using radiant heat which is a feature of a reduced pressure chemical vapor deposition (RPCVD) apparatus while a source gas is not supplied.

The graded composition layer is deposited at a temperature of 600 to 650° C. using an RPCVD technique, and the germanium composition gradient is increased gradually from a lower one to an upper one.

The germanium composition of the first constant composition layer is the same as a final germanium composition of the graded composition layer, and the germanium composition of the second constant composition layer is the same as or lower than that of the first constant composition layer.

The method further includes cleaning the surface of the first constant composition layer after planarizing the surface of the first constant composition layer.

### BRIEF DESCRIPTION OF THE DRAWINGS

The above and other features of the present invention will be described in reference to certain exemplary embodiments thereof with reference to the attached drawings in which:

FIG. 1 is a schematic cross-sectional view illustrating a silicon-based MOS transistor which employs a SiGe buffer layer in accordance with the present invention;

FIG. 2 is a cross-sectional view illustrating a process of forming a graded Si₁₋ₓGeₓ layer in accordance with the present invention;

FIG. 3 is a graph illustrating a change of the germanium composition and a thermal annealing condition depending on the deposition time;

FIGS. 4a to 4c are schematic views illustrating a process that stress is relaxed by a thermal annealing process;

FIGS. 5a and 5b are graphs illustrating measured results of a stress relaxation degree in a graded Si₁₋ₓGeₓ layer which is subjected to thermal annealing and a graded Si₁₋ₓGeₓ layer which is not subjected to thermal annealing;

FIGS. 6a and 6b are transmission electron microscope (TEM) cross-sectional photographs of a SiGe buffer layer which is not subjected to thermal annealing and a SiGe buffer layer which is subjected to thermal annealing;

FIGS. 7a to 7c are cross-sectional views illustrating a process of forming a constant Si_{1-Y}Ge_{y} layer in accordance with the present invention; and

FIGS. 8a and 8b are surface atomic force microscopy (AFM) photographs before a chemical mechanical polishing (CMP) planarization process and after deposition of a constant Si_{1-Y}Ge_{Y} layer

### DETAILED DESCRIPTION OF PREFERRED EMBODIMENTS

Exemplary embodiments of the present invention will now be described more fully with reference to the accompanying drawings. This invention may, however, be embodied in different forms and should not be construed as limited to the embodiments set forth herein. Rather, these embodiments are provided so that this disclosure will be thorough and complete, and will fully convey the scope of the invention to those skilled in the art.

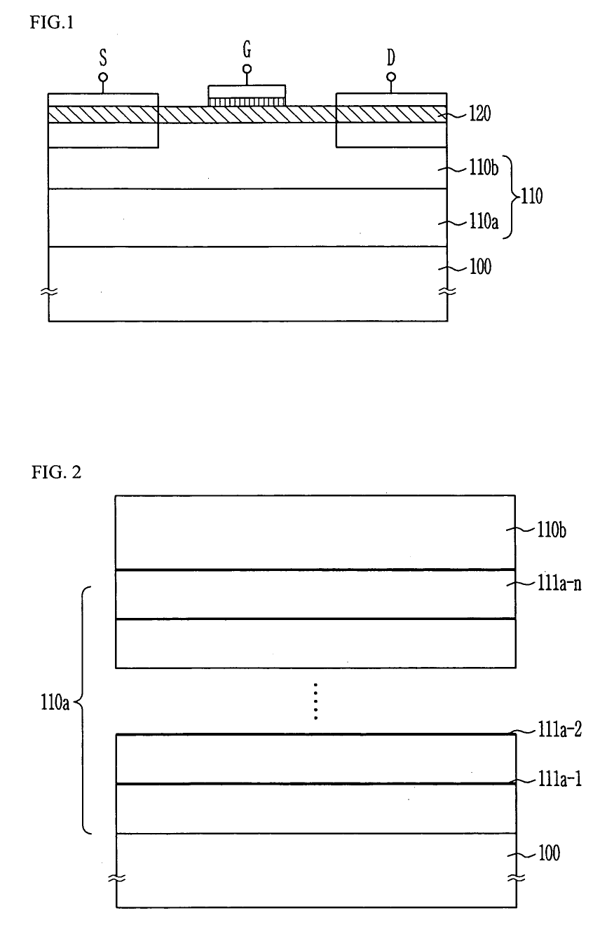

FIG. 1 is a cross-sectional view illustrating a silicon-based MOS transistor which employs a SiGe buffer layer in accordance with the present invention.

A SiGe buffer layer 110 including a graded composition layer, i.e., a graded Si₁₋ₓGeₓ layer 110a and a constant composition layer, i.e., constant Si_{1-y}Ge_{y} layer 110b which are formed on a silicon substrate 100. A gate of a MOS transistor is formed above the SiGe buffer layer 110, and a source S and a drain D are formed in both sides of the SiGe buffer layer 110, and a tensily strained silicon channel 120 is formed between the gate G and the SiGe buffer layer 110.

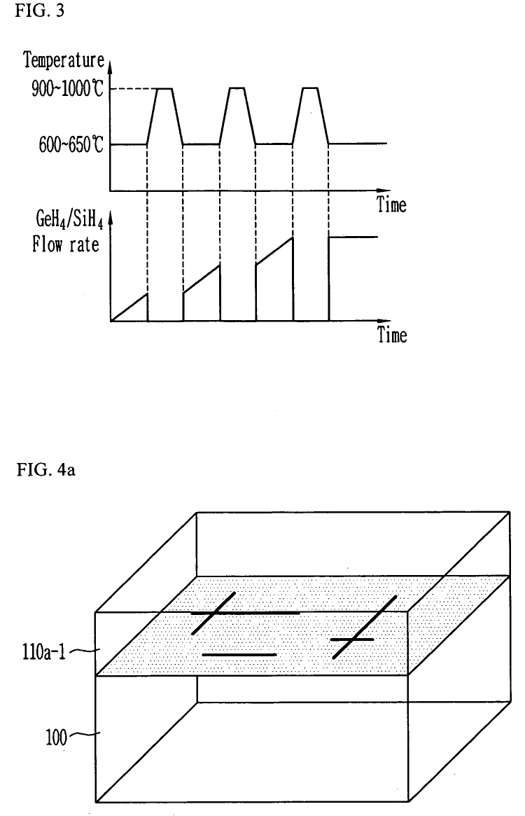

The graded Si₁₋ₓGeₓ layer 110a, as shown in FIG. 2a, is deposited to have a multi-layer structure, where n times of deposition processes are discontinuously performed to have a contstant composition gradient of from 0 to Y which is a germanium composition of the constant Si_{1-y}Ge_{y} layer 110b and a rapid thermal annealing process 111a-1 to 111a-n is performed in real time after one time deposition of the graded Si₁₋ₓGeₓ layer 110a. The graded Si₁₋ₓGeₓ layer 110a may be deposited by a reduced pressure chemical vapor deposition (RPCVD) apparatus, where the germanium composition can be varied linearly while increasing a flow of a GeH₄ gas which is a source gas of germanium at a temperature of about 600 to about 650° C. Also, the rapid thermal annealing process may be performed at a temperature of about 1000° C., for example, 900 to 1,000° C. using radiant heat which is a feature of the RPCVD apparatus. It is preferred that the graded Si₁₋ₓGeₓ layer 110a has 20% of the total thickness of the SiGe buffer layer 110, i.e., a thickness of 200 nm. The number of times of the rapid thermal annealing process may be determined by a composition of Y, but it is preferred to perform the thermal annealing process once whenever about 5% of germanium composition is varied. As described above, when the thermal annealing process is performed in real time whenever the graded Si₁₋ₓGeₓ layer 110a is deposited once, it can be seen from experiment that the stress is significantly relaxed in case of a germanium composition gradient of about 100% Ge/μm.

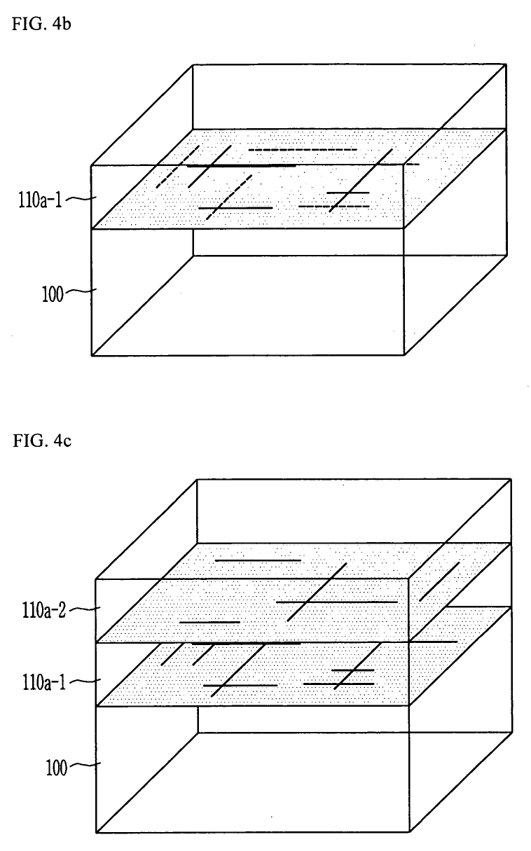

FIG. 3 is a view illustrating a deposition step and a thermal annealing step for forming the graded Si₁₋ₓGeₓ layer 110a.

A disposition step at a temperature of 600 to 650° C. and a thermal annealing step at a temperature of 900 to 1,000° C. are repeatedly performed. At the deposition step, a flow rate of a source gas GeH₄/SiH₄ is gradually increased, and at the thermal annealing step, a source gas GeH₄/SiH₄ is not injected. Using a feature of RPCVD which uses the radiant heat of a halogen lamp, a thermal annealing process can be performed for several minutes at a rapid ramping speed of 300° C./min.

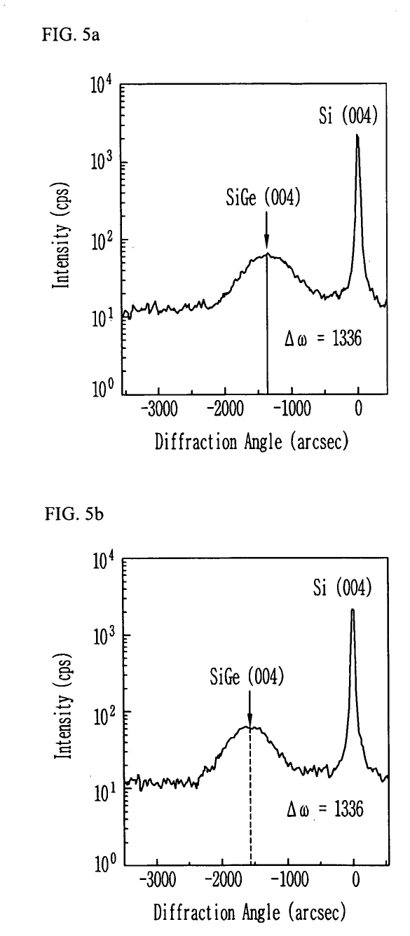

FIGS. 4a to 4c are schematic views illustrating a process that the stress is relaxed by a thermal annealing process.

Referring to FIG. 4a, a first graded Si₁₋ₓGeₓ layer 110a-1 is deposited on a silicon substrate 100. Misfit dislocation occurs at an interface due to a lattice constant difference from silicon, so that the stress relaxation is somewhat performed, but elastic deformation of a SiGe layer also remains.

Referring to FIG. 4b, a first high temperature thermal annealing process is performed to supply energy required for creation of the misfit dislocation, so that the misfit dislocation is increased, and the stress relaxation progresses more intensely.

Referring to FIG. 4c, a second graded Si₁₋ₓGeₓ layer 110a-2 is formed on the first graded Si₁₋ₓGeₓ layer 110a-1 which is subjected to first high temperature thermal annealing and then is subjected to second high temperature thermal annealing.

After depositing the graded Si₁₋ₓGeₓ layer, the stress relaxation progresses through the high temperature thermal annealing process, so that the misfit dislocation exists overall on the graded Si₁₋ₓGeₓ layer 110a, thereby the sufficient stress relaxation can be performed at a relatively small thickness. The high temperature thermal annealing process improves layer quality of the SiGe layer before forming the next graded Si₁₋ₓGeₓ layer, thereby preventing the misfit dislocation from being propagated to the next graded Si₁₋ₓGeₓ layer.

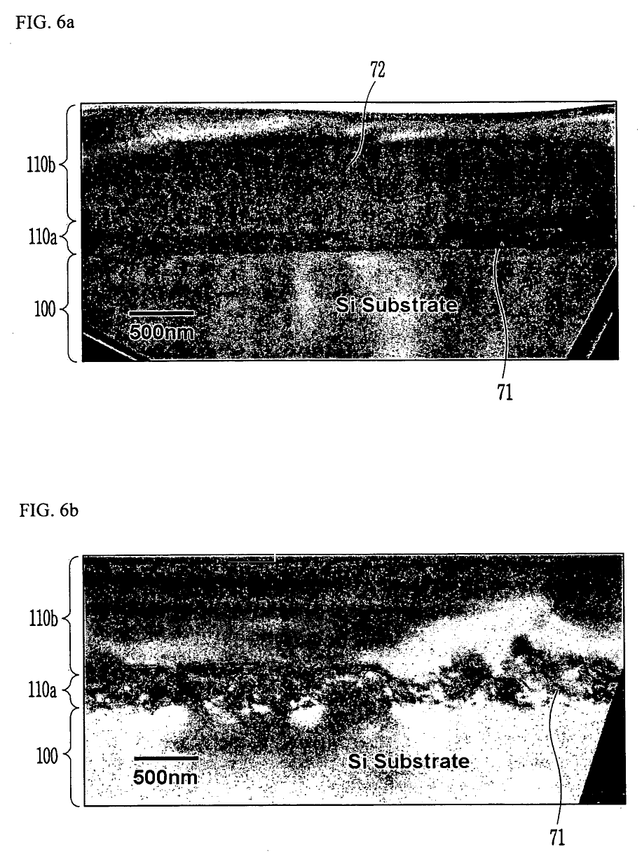

In order to confirm whether or not the high temperature thermal annealing process for forming the graded Si₁₋ₓGeₓ layer 110a contributes to the stress relaxation of the constant Si_{1-y}Ge_{y} layer, a dynamic X-ray diffraction (DXRD) rocking curve analysis was performed to a sample which has been subjected to thermal annealing or a sample which has not been subjected to thermal annealing. FIGS. 5a and 5b are graphs illustrating a measured stress relaxation degree. As can be seen in the graphs, the thermally annealed sample showed a stress relaxation degree of 96.5% (FIG. 5a), whereas, the sample which has not been subjected to thermal annealing showed a stress relaxation degree of 70.6% (FIG. 5b). It is understood that the stress relaxation progresses more intensely through the high temperature thermal annealing process.

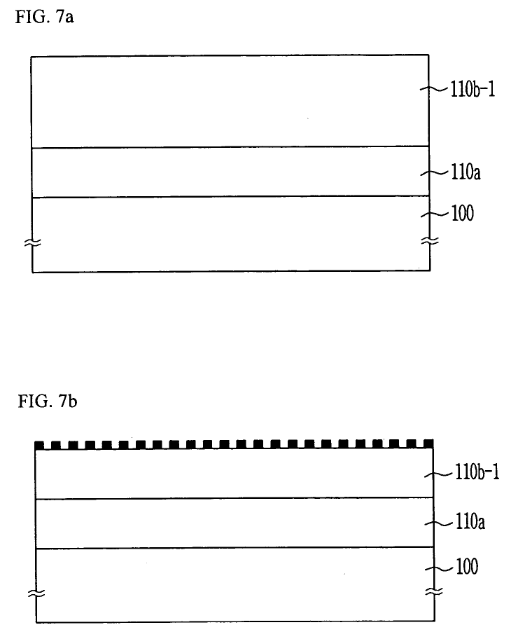

FIG. 6a is a TEM cross-sectional photograph of a SiGe buffer layer which has not been subjected to thermal annealing in accordance with the present invention. It can be seen that a surface is not smooth and some misfit dislocation 72 is propagated to the surface through the constant Si_{1-y}Ge_{y} layer 110b even though the misfit dislocation is shown overall on the graded Si₁₋ₓGeₓ layer 110a.

FIG. 6b is a TEM cross-sectional photograph of a SiGe buffer layer which has been subjected to thermal annealing in accordance with the present invention. It can be seen that a surface is smooth and the misfit dislocation 71 exists overall on the graded Si₁₋ₓGeₓ layer 110a.

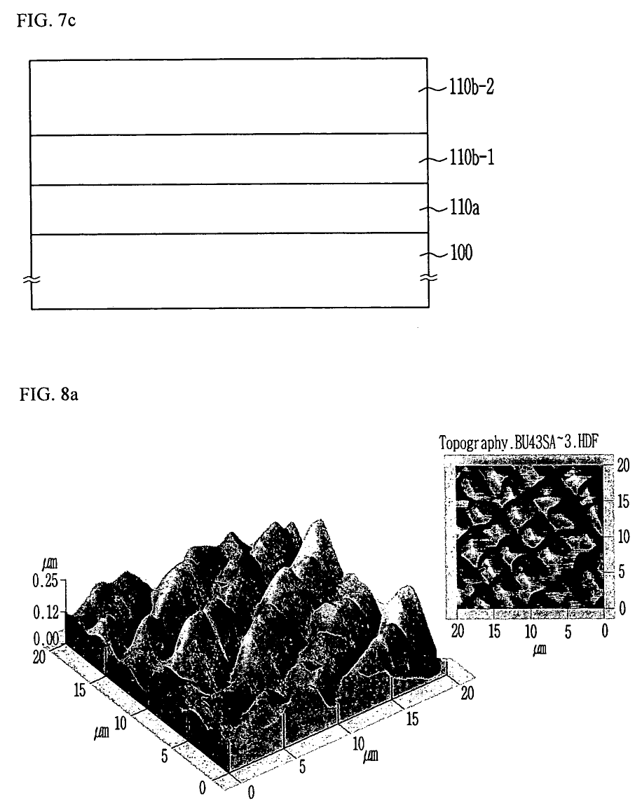

After forming a graded Si₁₋ₓGeₓ layer 110a having a desired germanium composition gradient, a constant Si_{1-y}Ge_{y} layer 110b is formed on the graded Si₁₋ₓGeₓ layer 110a. FIGS. 7a to 7c are cross-sectional views illustrating a process of forming the constant Si_{1-y}Ge_{y} layer 110b.

Referring to FIG. 7a, a graded Si₁₋ₓGeₓ layer 110a is formed on a silicon substrate 100 through the process described above. A constant Si_{1-y}Ge_{y} layer 110b-1 is deposited on the graded Si1-xGex layer 110a at a low temperature of 600° C., and then a thermal annealing process is performed for about one hour at a high temperature of 1100° C. in order to relax the remaining stress and get stability of a subsequent process. The constant Si1-yGey layer 1110b-1 is formed to a thickness of about 1 μm to get a process margin of a subsequent planarization process.

Referring to FIG. 7b, a surface of the constant Si_{1-y}Ge_{y} layer 110b-1 is polished by about 500 nm through a chemical mechanical polishing (“CMP”) process to thereby improve a surface roughness to become a bulk silicon level of about 0.5 nm.

Referring to FIG. 7c, foreign materials remaining on the surface of the constant Si_{1-y}Ge_{y} 110b-1 are removed using an SCI cleaning technique, and then the whole substrate is cleaned up again using a standard cleaning technique. Thereafter, a constant Si_{1-y}Ge_{y} layer 110b-2 is deposited on the constant Si_{1-y}Ge_{y} layer 110b-1 in a thickness of 300 nm. A germanium composition during deposition of the constant Si_{1-y}Ge_{y} layer 110b-2 is the same as or 1 Ge % less than the constant Si_{1-y}Ge_{y} layer 110b-1 to thereby remove even a very small stress.

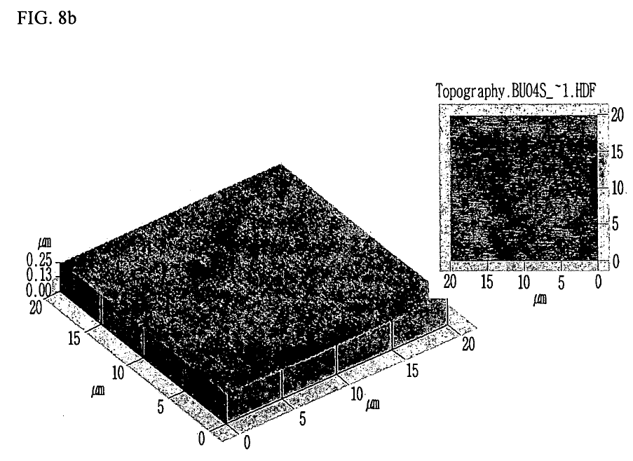

FIG. 8a is an AFM photograph of the constant Si_{1-y}Ge_{y} layer 110b-1 before a CMP planarization process, and FIG. 8b is a TEM cross-sectional photograph after depositing the constant Si_{1-y}Ge_{y} layer 110b-2.

FIG. 8a shows a surface of the constant Si_{1-y}Ge_{y} layer 110b-1 before a CMP planarization process, where an RMS value is 38.2 nm which is difficult to be applied to a device.

FIG. 8b is a TEM cross-sectional photograph of the deposited constant Si_{1-y}Ge_{y} layer 110b-2 after performing a CMP planarization process to improve the surface roughness and control the dislocation to be propagated to a surface. It can be seen that the surface is smoother than that of FIG. 8a, and the dislocation propagated to the surface is not shown.

The surface roughness before a CMP process was 38.2 nm (FIG. 8a), but the surface roughness after the CMP process was lowered to 0.5 nm. Even though the surface roughness was increased to 1.26 nm (FIG. 8b) after depositing the constant Si_{1-y}Ge_{y} layer 110b-2, the surface roughness was smooth enough to be applied to the device. It is understood that the surface cleaning has been effectively performed after the CMP planarization process and density of the dislocation which is propagated to the surface is less than 10⁴/cm², by a TEM cross-sectional photograph and an optical microscope analysis photograph using a SECCO etching technique.

As described above, the stress-relaxed SiGe buffer layer can be formed that has a relatively thin thickness, a low surface dislocation density, and a surface roughness similar to bulk silicon using a RPCVD technique with industrial mass-productivity. If the SiGe buffer layer of the present invention is applied to a MOSFET device or a MODFET device, a strained silicon or SiGe channel can be formed, and thus a device having excellent channel conductivity and high frequency characteristics can be manufactured.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

1. A method of forming a stress-relaxed SiGe buffer layer, comprising:
forming a graded composition layer having a predetermined germanium composition gradient on a silicon substrate;
forming and thermally annealing a first constant composition layer having a predetermined germanium composition on the graded composition layer;
removing the first constant composition layer by a predetermined thickness to planarize a surface; and
forming a second constant composition layer on the first constant composition layer to form a SiGe buffer layer having the graded composition layer and the constant composition layer.

2. The method as set forth in claim 1, wherein the graded composition layer is formed by a SiGe deposition process and a thermal annealing process for increasing misfit dislocation, and the deposition process and the thermal annealing process are repeatedly performed by a predetermined number of times.

3. The method as set forth in claim 2, wherein the thermal annealing process is performed at a temperature of 900 to 1000° C. using radiant heat which is a feature of a reduced pressure chemical vapor deposition (RPCVD) apparatus while a source gas is not supplied.

4. The method as set forth in claim 1, wherein the graded composition layer is deposited at a temperature of 600 to 650° C. using a RPCVD technique, and the germanium composition gradient is increased gradually from a lower one to an upper one.

5. The method as set forth in claim 4, wherein the germanium composition gradient is in a range of 50 to 200% Ge/μm.

6. The method as set forth in claim 1, wherein the germanium composition of the first constant composition layer is the same as a final germanium composition of the graded composition layer, and the germanium composition of the second constant composition layer is the same as or lower than that of the first constant composition layer.

7. The method as set forth in claim 1, wherein the planarization is performed by a chemical mechanical polishing (CMP) process.

8. The method as set forth in claim 1, further comprising cleaning the surface of the first constant composition layer after planarizing the surface of the first constant composition layer.

9. The method as set forth in claim 8, wherein the cleaning process is performed by an SC-1 cleaning method and a standard cleaning method.
